(19) United States
(12) Patent Application Publication
(10) Pub. No.: US 2016/0118578 A1
(43) Pub. Date: Apr. 28, 2016

(54) MAGNETIC MEMORY DEVICE AND METHOD OF MANUFACTURING THE SAME

(71) Applicants: Jong Chul PARK, Seongnam-si (KR); Shin Jae KANG, Seoul (KR)

(72) Inventors: Jong Chul PARK, Seongnam-si (KR); Shin Jae KANG, Seoul (KR)

(21) Appl. No.: 14/825,161

(22) Filed: Aug. 12, 2015

(30) Foreign Application Priority Data
Oct. 24, 2014 (KR) 10-2014-0145276

(51) Int. Cl. H01L 43/12; G11C 11/16; H01L 43/10; H01L 27/22; H01L 43/02; H01L 43/08

(52) U.S. Cl. CPC H01L 43/12; H01L 43/02; H01L 43/08; H01L 43/10; H01L 27/222; G11C 11/161

(57) ABSTRACT

A method of manufacturing a magnetic memory device includes forming a lower magnetic layer, a tunnel barrier layer, and an upper magnetic layer on a substrate, forming a magnetic tunnel junction (MTJ) pattern by patterning the lower magnetic layer, the tunnel barrier layer, and the upper magnetic layer, and irradiating a side wall of the MTJ pattern using a beam including an oxygen ion, wherein, in the forming of the MTJ pattern, a metal redeposition material covering the side wall of the MTJ pattern is formed and the beam is radiated to the metal redeposition material.

### CROSS-REFERENCE TO RELATED APPLICATION

This application claims priority under 35 U.S.C. §119 to Korean Patent Application No. 10-2014-0145276 filed on Oct. 24, 2014, with the Korean Intellectual Property Office, the disclosure of which is incorporated herein by reference.

### BACKGROUND

The present inventive concepts relate to a magnetic memory device and a method of manufacturing a magnetic memory device.

A magnetic memory is a nonvolatile memory device storing data (data reading and writing) using a magnetic tunnel junction pattern including two magnetic materials and an insulating layer interposed therebetween. A resistance value of the magnetic tunnel junction pattern may vary according to directions in which the two magnetic materials are magnetized, and here, data may be written thereon or erased therefrom using a difference in resistance values. Thereamong, a magnetic memory device using the phenomenon of spin transfer torque (STT) uses a scheme of varying a magnetization direction of a magnetic material according to spin transfer of electrons when a spin-polarized current is applied in one direction.

### SUMMARY

An aspect of the present inventive concepts may provide a magnetic memory device having improved magnetic tunnel characteristics and a manufacturing method thereof.

According to an aspect of the present inventive concepts, a method of manufacturing a magnetic memory device may include: forming a lower magnetic layer, a tunnel barrier layer, and an upper magnetic layer on a substrate; forming a magnetic tunnel junction (MTJ) pattern by patterning the lower magnetic layer, the tunnel barrier layer, and the upper magnetic layer; and irradiating a side wall of the MTJ pattern using a beam including an oxygen ion, wherein, in the forming of the MTJ pattern, a metal redeposition material covering the side wall of the MTJ pattern is formed, and the beam is used to irradiate the metal redeposition material.

The metal redeposition material may be formed by removal of portions of the upper and lower magnetic layers and deposition thereof on the side wall of the MTJ pattern.

The oxygen ion may oxidize at least a portion of the metal redeposition material.

At least a portion of the metal redeposition material may be removed by the beam.

The beam may include an inert gas ion.

The beam may be incident at an angle ranging from about 15 degrees to about 35 degrees with respect to the substrate.

The irradiating process may be performed by ion beam etching.

A dose of the oxygen ion may be adjusted such that the oxygen ion may not penetrate to the interior of the MTJ pattern.

The content of the oxygen ion of the beam may range from about 1% to about 30%.

The forming of the MTJ pattern may be performed by dry etching.

The tunnel bather layer may be formed of any one selected from the group consisting of magnesium oxide (MgO), an aluminum oxide (Al₂O₃), a silicon oxide (SiO₂), and a boron oxide (B₂O₃).

In the forming of the MTJ pattern, the metal redeposition material may be formed on the side wall of the MTJ pattern, and the method may further include forming a side wall protective layer on the metal redeposition material before the irradiating beam is supplied.

The side wall protective layer may be formed of an insulating material.

According to another aspect of the present disclosure, a method of manufacturing a magnetic memory device may include: forming a magnetic tunnel junction (MTJ) pattern on a substrate by dry-etching a lower magnetic layer, a tunnel barrier layer, and an upper magnetic layer, wherein a metal layer covering a side wall of the MTJ pattern is formed; and forming a side wall insulating layer by irradiating using a beam including a reactive ion with respect to the metal layer and further including an inert gas ion.

A dose of the reactive ion may be adjusted such that the reactive ion may not penetrate to the interior of the MTJ pattern.

The reactive ion may form a metal insulating material by reacting with the metal layer.

The reactive ion may be an oxygen ion or a nitrogen ion.

According to another aspect of the present disclosure, a method of manufacturing a magnetic memory device may include: forming a magnetic tunnel junction (MTJ) pattern by patterning a lower magnetic layer, a tunnel layer, and an upper magnetic layer formed on a substrate; and forming a side wall insulating layer by irradiating using a beam including a reactive ion with respect to the metal layer and an inert gas ion.

The irradiating process may be performed by ion beam etching.

The beam may include an inert gas ion.

According to another aspect of the present disclosure, a magnetic memory device may include: a lower electrode patterned in at least a portion thereof and disposed on a substrate; a magnetic tunnel junction (MTJ) pattern disposed on the lower electrode and including a lower magnetic layer, a tunnel barrier layer, and an upper magnetic layer; and a side wall insulating layer covering a side wall of the MTJ pattern and a side wall of the lower electrode.

The side wall insulating layer may include at least one oxide of the upper magnetic layer, the lower magnetic layer, and the lower electrode.

The side wall insulating layer may extend from the side wall of the lower electrode in a direction parallel to the substrate.

According to another aspect of the present disclosure, a magnetic memory device may include: a magnetic tunnel junction (MTJ) pattern including a lower magnetic layer, a tunnel barrier layer, and an upper magnetic layer; a metal oxide layer covering a side wall of the MTJ pattern; and a side wall protective layer covering the metal oxide layer.

The metal oxide layer may include a metal oxide of the upper magnetic layer or the lower magnetic layer.

The side wall protective layer may be formed of an insulating material.

### BRIEF DESCRIPTION OF DRAWINGS

The above and other aspects, features and other advantages of the present inventive concepts will be more clearly understood from the following detailed description taken in conjunction with the accompanying drawings, in which:

FIG. 1 is a circuit diagram illustrating a cell array of a magnetic memory device according to an exemplary embodiment of the present inventive concepts;

FIG. 2 is a plan view of the magnetic memory device according to an exemplary embodiment of the present inventive concepts;

FIG. 3 is a cross-sectional view of the magnetic memory device according to an exemplary embodiment of the present inventive concepts, taken along lines I-I′ and II-II′ of FIG. 2;

FIGS. 4A through 4E are cross-sectional views illustrating sequential processes of a method of manufacturing a magnetic memory device according to an exemplary embodiment of the present inventive concepts, taken along line I-I′ of FIG. 2;

FIG. 5 is a cross-sectional view illustrating a magnetic memory device according to an exemplary embodiment of the present inventive concepts;

FIGS. 6A and 6B are cross-sectional views illustrating sequential processes of a method of manufacturing a magnetic memory device according to an exemplary embodiment of the present inventive concepts, taken along line I-I′ of FIG. 2;

FIG. 7 is a circuit diagram illustrating a cell array of a magnetic memory device according to an exemplary embodiment of the present inventive concepts;

FIG. 8 is a plan view of a magnetic memory device according to an exemplary embodiment of the present inventive concepts;

FIG. 9 is a cross-sectional view of the magnetic memory device according to an exemplary embodiment of the present inventive concepts, taken along lines I-I′ and II-II′ of FIG. 8;

FIGS. 10A through 10D are cross-sectional views illustrating sequential processes of a method of manufacturing a magnetic memory device according to an exemplary embodiment of the present inventive concepts, taken along line I-I′ of FIG. 8; and

FIGS. 11 and 12 are block diagrams illustrating an electronic device including a magnetic memory device according to an exemplary embodiment of the present inventive concepts.

### DETAILED DESCRIPTION

Hereinafter, exemplary embodiments of the present inventive concepts will be described in detail with reference to the accompanying drawings.

Various embodiments will now be described more fully with reference to the accompanying drawings in which some embodiments are shown. The present disclosure may, however, be embodied in different forms and should not be construed as limited to the embodiments set forth herein. Rather, these embodiments are provided so that this disclosure is thorough, complete, and fully conveys the present disclosure to those skilled in the art. In the drawings, the sizes and relative sizes of layers and regions may be exaggerated for clarity.

Exemplary embodiments of the present inventive concepts are not limited to particular configurations but may include a change in configurations generated according to manufacturing processes. For example, an etched region illustrated as being at a right angle may be rounded or may have a shape having a predetermined degree of curvature. Thus, regions illustrated in the drawings may have rough attributes, and the shapes of regions illustrated in the drawings exemplify particular shapes without limiting the scope of the present inventive concepts.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It will be understood that when an element or layer is referred to as being “on,” “connected to” or “coupled to” another element or layer, it can be directly on, connected to or coupled to the other element or layer, or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, when an embodiment can be implemented differently, functions or operations described in a particular block may occur in a different way from a flow described in the flowchart. For example, two consecutive blocks may be performed simultaneously, or the blocks may be performed in reverse according to related functions or operations.

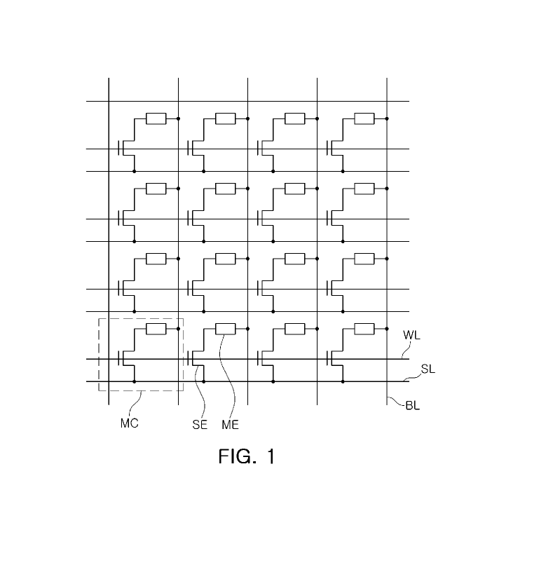

FIG. 1 is a circuit diagram illustrating a cell array of a magnetic memory device according to an exemplary embodiment of the present disclosure.

Referring to FIG. 1, a cell array of a magnetic memory device includes a plurality of unit cells MC arranged in a matrix form. Each of the plurality of unit cells MC of the magnetic memory device may include a select element SE and a magnetic memory element ME. Each of the plurality of unit cells MC of the magnetic memory device is electrically connected to a corresponding word line WL and a corresponding bit line BL. Also, as illustrated in FIG. 1, when the select element SE is a transistor, each of the plurality of unit cells MC of the magnetic memory device may further be connected to a source line SL, which is electrically connected to a source region of the select element SE. The word line WL and the bit line BL may be arranged at a predetermined angle with respect to each other, for example, to be perpendicular to each other two-dimensionally. Also, the word line WL and the source line SL may be arranged at a predetermined angle with respect to each other, for example, to be parallel.

The magnetic memory element ME may include a magnetic tunnel junction (MTJ). Also, the magnetic memory element ME may serve as a memory using a spin torque transfer (STT) phenomenon in which a magnetization direction of a magnet is varied by an input current. The select element SE may be configured to selectively control a flow of electric charges passing through the magnetic tunnel junction (MTJ). For example, the select element SE may, for example, be a diode, a PNP bipolar transistor, an NPN bipolar transistor, an NMOS field effect transistor, and/or a PMOS field effect transistor.

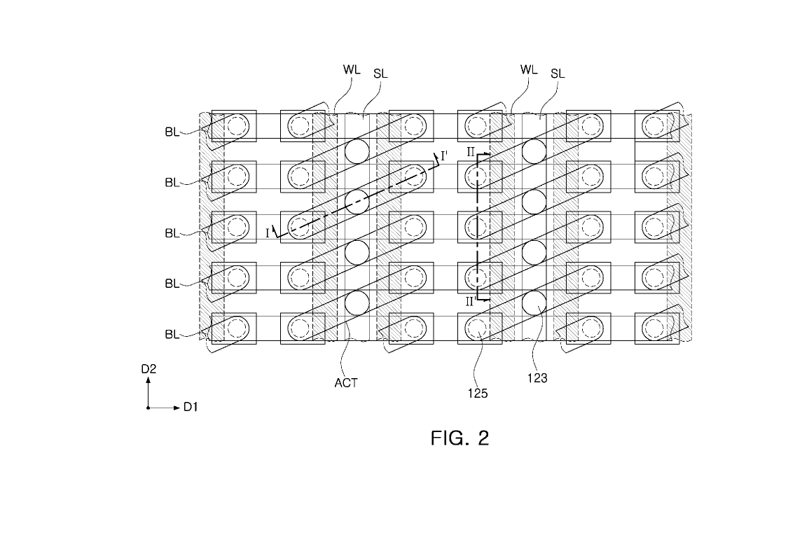

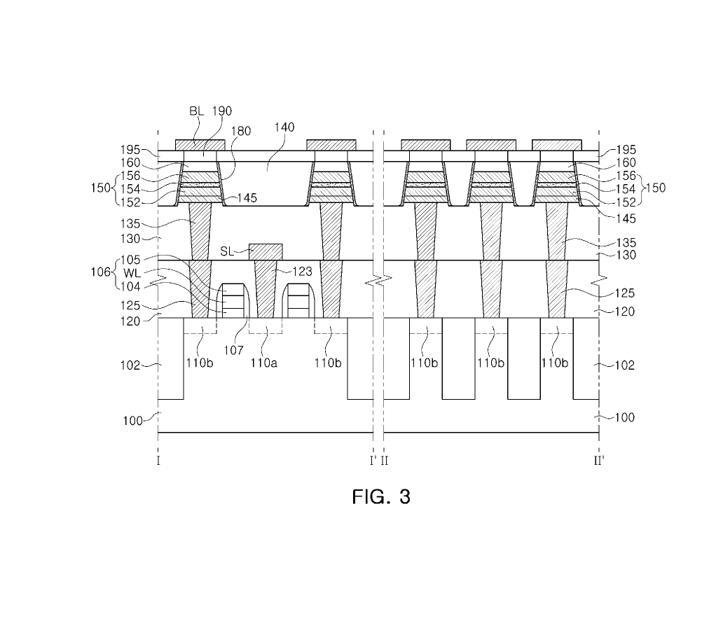

FIG. 2 is a plan view of a magnetic memory device according to an exemplary embodiment the present inventive concepts. FIG. 3 is a cross-sectional view of the magnetic memory device according to an exemplary embodiment of the present inventive concepts, taken along lines I-I′ and II-II′ of FIG. 2.

Referring to FIGS. 2 and 3, isolation patterns 102 defining active patterns ACT may be formed on a substrate 100. The substrate 100 may, for example, be a silicon substrate, a germanium substrate, and/or a silicon-germanium substrate.

The active patterns ACT may be arranged two-dimensionally in a plurality of rows and a plurality of columns, and the active patterns ACT may each have a substantially rectangular shape (e.g., a bar shape) extending in a direction that is diagonal with respect to first and second directions D1 and D2, respectively. The first and second directions, D1 and D2, respectively, may be arranged perpendicular to each other. The active patterns ACT may be sequentially arranged in the first direction D1 to form rows, and may be sequentially arranged in the second direction D2 to form column The active patterns ACT may be doped with a first conductivity-type dopant.

A gate 106 forming a word line WL may be disposed on the substrate 100. The gate 106 may include a gate insulating layer pattern 104, a word line WL, and a gate mask 105. A spacer 107 may be disposed on side walls of the gate 106.

A first impurity region 110a and a second impurity region 110b may be formed in regions adjacent to the gate 106 on the substrate 100.

A first interlayer insulating layer 120 may be disposed on the entire surface of the substrate 100. The first interlayer insulating layer 120 may be formed of an oxide (for example, a silicon oxide). First and second contact plugs 123 and 125 may penetrate through the first interlayer insulating layer 120. The first contact plug 123 may be electrically connected to the first impurity region 110a. The second contact plugs 125 may be electrically connected to the second impurity regions 110b.

The first and second contact plugs 123 and 125, respectively, may include at least one material selected from among a semiconductor material doped with a dopant (for example, doped silicon or the like), a metal (for example, tungsten, aluminum, titanium, and/or tantalum), a conductive metal nitride (for example, a titanium nitride, a tantalum nitride, and/or a tungsten nitride), and a metal-semiconductor compound (for example, a metal silicide).

Source lines SL extending in the second direction D2 may be disposed on the first interlayer insulating layer 120. The source lines SL may be disposed to traverse the word lines WL. Each of the source lines SL may be connected to a plurality of the first contact plugs 123 arranged in the second direction D2.

A second interlayer insulating layer 130 may be disposed on the first interlayer insulating layer 120, and the second interlayer insulating layer 130 may cover the second contact plugs 125 and the source lines SL.

The first and second contact plugs 123 and 125, respectively, may include at least one material selected from among a semiconductor material doped with a dopant (for example, doped silicon or the like), a metal (for example, tungsten, aluminum, titanium, and/or tantalum), a conductive metal nitride (for example, a titanium nitride, a tantalum nitride, and/or a tungsten nitride), and a metal-semiconductor compound (for example, a metal silicide).

Lower contacts 135 may be disposed to penetrate through the second interlayer insulating layer 130, and each of the lower contacts 135 may be electrically connected to the second contact plugs 125, respectively. In an exemplary embodiment, the lower contacts 135 may be arranged to be spaced apart from one another in the first direction D1 and the second direction D2 in a planar manner. The lower contacts 135 may be arranged in a zigzag form in the planar manner.

Lower electrodes 145 may be disposed on the lower contacts 135. The lower electrodes 145 may include a conductive material such as titanium, tantalum, ruthenium, a titanium nitride, a tantalum nitride, tungsten, and the like. These materials may be used alone or in combination. For example, the lower electrodes 145 may have a dual-layer structure such as ruthenium/titanium, ruthenium/tantalum, a ruthenium/titanium nitride, a ruthenium/tantalum nitride, or titanium nitride/tungsten.

A magnetic tunnel junction (MTJ) pattern 150 may be provided. The MTJ pattern 150 may include a lower magnetic layer 152 and a tunnel barrier layer 154 and an upper magnetic layer 156 sequentially disposed on the lower magnetic layer 152.

At least a portion of the lower electrode 145 may be patterned simultaneously when the MTJ pattern 150 is being patterned.

In the present exemplary embodiment, a perpendicular magnetic tunnel junction device in which the lower magnetic layer 152 serves as a pinned layer (or a fixed layer) and the upper magnetic layer 156 serves as a free layer will be described as an example, but any MTJ device could be used. For example, a perpendicular magnetic tunnel junction device in which the lower magnetic layer 152 serves as a free layer and the upper magnetic layer 156 serves as a pinned layer may also or alternatively be formed.

The lower magnetic layer 152 may include an antiferromagnetic material layer. A magnetization direction of the antiferromagnetic material layer may be fixed as a direction substantially parallel to the substrate. The antiferromagnetic material layer may include, for example, a platinum-manganese (Pt—Mn) alloy, an iridium-manganese (Ir—Mn) alloy, a nickel-manganese (Ni—Mn) alloy, an iron-manganese (Fe—Mn) alloy, and/or the like.

A ferromagnetic material layer may be disposed on the antiferromagnetic material layer of the lower magnetic layer 152. A magnetization direction of the ferromagnetic material layer may be fixed by the antiferromagnetic material layer. For example, the ferromagnetic material layer may include cobalt (Co), iron (Fe), platinum (Pt), palladium (Pd), and/or the like, and may have a synthetic antiferromagnet (SAF) structure. The SAF structure may be a multilayer structure in which a plurality of magnetic layers and at least one intermediate layer are sequentially stacked. For example, the SAF structure may be a multilayer structure in which a first magnetic layer, an intermediate layer, and a second magnetic layer are sequentially stacked. The SAF structure may alternatively be a multilayer structure in which a first magnetic layer, a first intermediate layer, a second magnetic layer, a second intermediate layer, and a third magnetic layer are sequentially stacked. The first magnetic layer may, for instance, include a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, a Ni—Fe alloy, a Co—Fe alloy, a Ni—Fe—B alloy, a Co—Fe—B alloy, a Ni—Fe—Si—B alloy, a Co—Fe—Si—B alloy, and/or the like. The second and third magnetic layers may include a monolayer formed of cobalt (Co), iron (Fe), platinum (Pt), palladium (Pd), and/or the like, or multiple layers thereof, and the intermediate layer may include ruthenium (Ru), tantalum (Ta), chromium (Cr), copper (Cu), and/or the like.

The tunnel barrier layer 154 may be disposed on the lower magnetic layer 152.

The tunnel barrier layer 154 may, for instance, include any one or more materials selected from the group consisting of a magnesium oxide (MgO), an aluminum oxide (Al₂O₃), a silicon oxide (SiO₂), and a boron oxide (B₂O₃).

The upper magnetic layer 156 may be disposed on the tunnel barrier layer 154. The upper magnetic layer 156 may include at least one material selected from the group consisting of iron (Fe), cobalt (Co), nickel (Ni), palladium (Pd), and platinum (Pt). For example, the upper magnetic layer 156 may include an Fe—Pt alloy, an Fe—Pd alloy, a Co—Pd alloy, a Co—Pt alloy, an Fe—Ni—Pt alloy, a Co—Fe—Pt alloy, a Co—Ni—Pt alloy, and/or the like. In another exemplary embodiment, the upper magnetic layer 156 may include at least one material selected from the group consisting of boron (B), carbon (C), copper (Cu), silver (Ag), gold (Au), and chromium (Cr).

An upper electrode 160 may be disposed on the MTJ pattern 150. The upper electrode 160 may include a monolayer formed of a conductive material such as titanium, tantalum, ruthenium, a titanium nitride, a tantalum nitride, tungsten, and/or the like, or multiple layers thereof.

A side wall insulating layer 180 may be formed to cover side walls of the MTJ pattern 150 and the upper electrode 160. The side wall insulating layer 180 may include a metal oxide formed by oxidizing a metal included in the MTJ pattern 150 and the upper electrode 160.

A third interlayer insulating layer 140 may be disposed on the second interlayer insulating layer 130 to cover the side walls of the side wall insulating layer 180, and a fourth interlayer insulating layer 195 may be disposed on the third interlayer insulating layer 140. An upper contact 190 penetrating through the fourth interlayer insulating layer 195 may be disposed on the upper electrode 160. A bit line BL may be disposed on the upper contact 190 and the fourth interlayer insulating layer 195.

The interlayer insulating layers 120, 130, 140, and 195 may include, for example, at least one material selected from the group consisting of boro-phospho-silicate glass (BPSG), tonen silazene (TOSZ), undoped silicate glass (SOG), flowable oxide (FOX), tetraethylortho silicate (TEOS), and a high density plasma chemical vapor deposition (HDP-CVD) oxide.

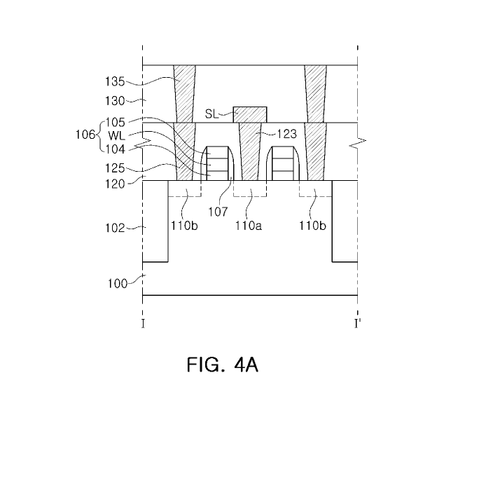

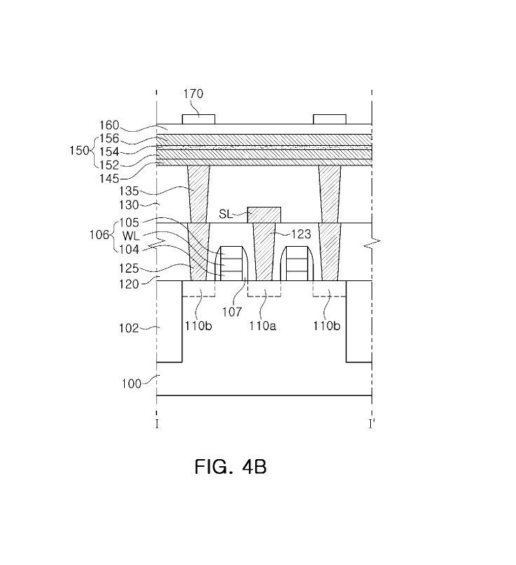

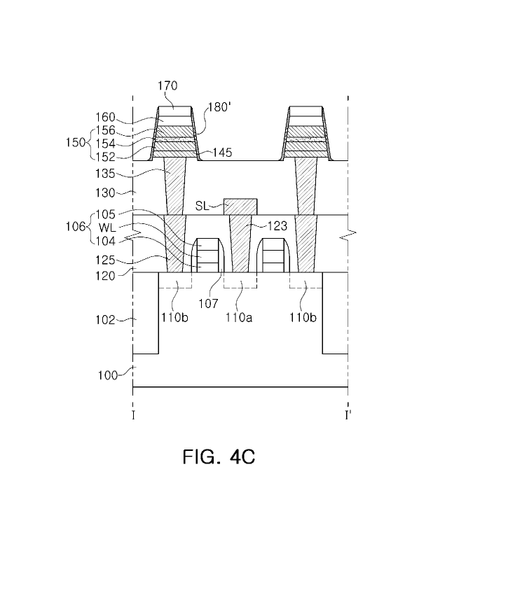

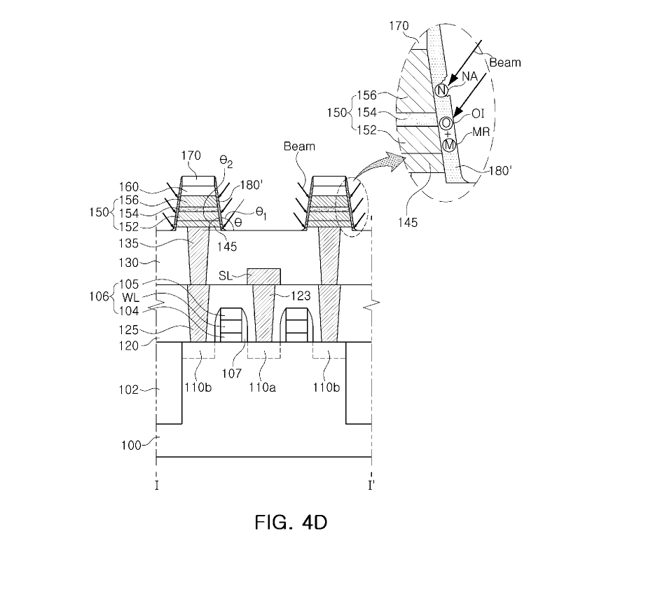

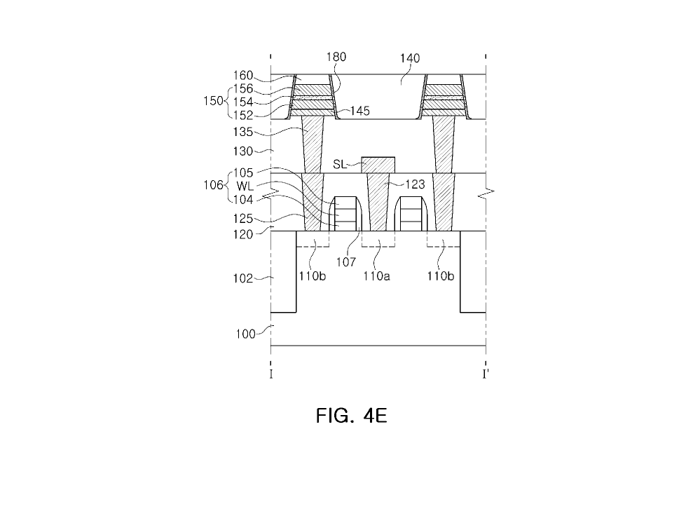

FIGS. 4A through 4E are cross-sectional views illustrating sequential processes of a method of manufacturing a magnetic memory device according to an exemplary embodiment of the present inventive concepts, taken along line I-I′ of FIG. 2.

Referring to FIG. 4A, the isolation layer 102 is formed on the substrate 100. The isolation layer 102 may be formed through a shallow trench isolation (STI) process.

The gate insulating layer 104, the word line WL, and the gate mask layer 105 may be sequentially disposed on the substrate 100 and patterned through a photolithography process to form gates 106. The gate insulating layer 104 may be formed using a silicon oxide or a metal oxide. The word line WL may be formed using a doped polysilicon or metal. The gate mask layer 105 may be formed using a silicon nitride.

Thereafter, the first and second impurity regions 110a and 110b, respectively, may be formed to be adjacent to the gates 106 through an ion implantation process using the gates 106 as ion implantation masks. The first and second impurity regions 110a and 110b, respectively, may serve as source and drain regions of transistors including the gates 106.

The gate 106 and the first and second impurity regions 110a and 110b, respectively, may constitute a transistor. The spacer 107 may be formed on side walls of the gate 106 using a silicon nitride.

Thereafter, the first interlayer insulating layer 120 covering the gate 106 and the spacer 107 may be formed on the substrate 100. The first interlayer insulating layer 120 may be partially etched to form first holes exposing the impurity regions 110a and 110b.

Thereafter, a first conductive film embedding the first holes may be formed on the first interlayer insulating layer 120, and upper portions of the first conductive film may be removed through a chemical mechanical polishing (CMP) and/or etchback process until the first interlayer insulating layer 120 is exposed. This process thereby forms the first contact plugs 123 and the second contact plugs 125 in the first holes. The first contact plugs 123 may be in contact with the first impurity region 110a and the second contact plugs 125 may be in contact with the second impurity regions 110b. The first conductive film may be formed using a doped polysilicon, a metal, and/or the like. The first contact plugs 123 may serve as a source line (SL) contact.

A second conductive film may be formed on the first interlayer insulating layer 120 in contact with the first contact plugs 123 and may be patterned to form a source line SL. The second conductive film may be formed using a doped polysilicon, a metal, and/or the like. Thereafter, the second interlayer insulating layer 130 covering the source line SL may be formed on the first interlayer insulating layer 120. The second interlayer insulating layer 130 may be partially etched to form second holes exposing the second contact plugs 125, and a third conductive film embedding the second holes may be formed on the second contact plugs 125 and the second interlayer insulating layer 130. Upper portions of the third conductive film may be removed through a CMP and/or etchback process until the second interlayer insulating layer 130 is exposed, thereby forming lower contacts 135 within the second holes.

Referring to FIG. 4B, the lower electrode 145 may be formed on the second insulating layer 130 and the lower contact holes 135. The lower electrode 145 may be formed, for example, through an atomic layer deposition (ALD) process, a chemical vapor deposition (CVD) process, and/or the like, using a conductive material such as titanium, tantalum, ruthenium, a titanium nitride, a tantalum nitride, and/or tungsten. The lower electrode 145 may have a dual-layer structure, for example, such as ruthenium/titanium, ruthenium/tantalum, a ruthenium/titanium nitride, a ruthenium/tantalum nitride, or titanium nitride/tungsten.

The lower magnetic layer 152, the tunnel barrier layer 154, the upper magnetic layer 156, and the upper electrode 160 may be sequentially formed on the lower electrode 145. The lower magnetic layer 152, the tunnel barrier layer 154, the upper magnetic layer 156, and the upper electrode 160 may, for instance, be formed through a CVD process or an ALD process.

The mask patterns 170 may be formed on the upper electrode 160 such that the mask patterns 170 correspond to the positions of the lower contacts 135. The mask patterns 170 may be photoresist patterns or may be hard mask patterns including a silicon oxide, a silicon nitride, and/or the like.

Referring to FIG. 4C, the lower magnetic layer 152, the tunnel barrier layer 154, the upper magnetic layer 156, and the upper electrode 160 may be patterned using the mask patterns 170 as etching masks to form the MTJ patterns 150. Here, at least a portion of the lower electrode 145 may be patterned.

The patterning may be performed by dry etching. More specifically, the patterning may be performed using a light ion etching process or a light ion plasma etching process. The light ion etching process may be performed using at least one of hydrogen (H), helium (He), nitrogen (N), argon (Ar), and neon (Ne), for example. While the etching process is being performed, the upper surface of the second interlayer insulating layer 130 exposed between the MTJ patterns 150 may be recessed.

During the patterning process, a metal redeposition material 180′ may be formed by redeposition of etching residue so that the side walls of the upper electrode, the MTJ patterns 150, and the lower electrode 145 may be covered. In this disclosure, “etching residue” is a term indicating a residual material, which has not been removed after etching. The etching residue may include a metal forming the upper and lower magnetic layers 152 and 156, respectively, included in the MTJ patterns 150, and/or a metal forming the upper and lower electrodes 145 and 160, respectively. Here, the upper and lower magnetic layers 152 and 156, respectively, may be electrically connected to each other by the metal redeposition material 180′ (which may be a conductive material), and the memory device may thereby become defective due to an electrical short circuit caused by the etching residue.

Referring to FIG. 4D, a beam including a reactive ion with respect to the metal forming the metal redeposition material 180′ may be irradiated to the metal redeposition material 180′. The reactive ion may react with the metal, thereby forming a metal insulating material. More specifically, the reactive ion may be an oxygen ion or a nitrogen ion, and the metal insulating material may be a metal oxide or a metal nitride. The beam irradiation may be performed, for instance, by ion beam etching. The beam may further include an inert gas ion NA, and the inert gas ion NA may remove a portion of the metal redeposition material 180′ by etching. More specifically, the inert gas ion NA may be a noble gas ion such as a helium (He), neon (Ne), or argon (Ar) gas ion. An oxygen ion (OI) may penetrate through a portion of the side wall from which the metal redeposition material 180′ has been removed, and may react with at least a portion of a metal MR of the metal redeposition material 180′ to form a metal oxide. By forming the metal oxide, the metal redeposition material 180′ may be changed into a side wall insulating layer 180 (see FIG. 4E) and electrical short circuits in the memory device may thereby be prevented. The side wall insulating layer 180 (see FIG. 4E) may additionally extend from the side wall of the lower electrode 145 in a direction parallel to the substrate 100.

The beam used in the irradiation process may, for example, be incident to the metal redeposition material 180′ at an angle (θ) (measured between the beam and the substrate 100) that ranges from about 15 degrees to about 35 degrees. If the angle (θ) of the beam is outside of the desired range, the inert gas ion NA may not easily remove the metal redeposition material 180′ and the oxygen ion OI may not easily penetrate through the interior of the metal redeposition material 180′, thereby resulting in an insufficient formation of a metal oxide. The angle (θ) between the beam and the substrate has a relationship with an angle (θ₁) between the side wall of the MTJ pattern 150 and the beam and an angle (θ₂) between the side wall of the MTJ pattern 150 and the substrate 100, as expressed by Equation 1.

θ₁=180°−θ-θ₂ (1)

θ₂ may have an angle ranging from about 70 degrees to about 90 degrees. Thus, when θ is an angle ranging from about 15 degrees to about 35 degrees, the angle θ₁ may range from about 55 degrees to about 95 degrees.

Ion beam energy and/or a dose of the oxygen ion OI may be adjusted such that the metal redeposition material 180′ is oxidized, while preventing oxygen from being diffused to the interior of the MTJ pattern 150. Or, in other words, when irradiating using oxygen ions OI, ion beam energy and the content of the oxygen may be adjusted such that the oxygen will not penetrate to the interior of the MTJ element while the metal redeposition material is being oxidized.

If oxygen ions were permitted to penetrate to the interior of the MTJ, for example, when the tunnel barrier layer 154 is a metal oxide and the upper and lower magnetic layers 152 and 156 are CoFeB, Fe—O bonding may be inhibited by the oxygen ions diffused through the tunnel barrier layer 154, and the characteristics of the MTJ pattern 150 might be significantly degraded.

In an example embodiment, ion beam energy may be about 300 eV or less. If the ion beam energy exceeds 300 eV, an excessive amount of oxygen ions OI may penetrate to the interior of the MTJ pattern 150 due to the high energy of the ion beam. Penetration into the MTJ pattern 150 could inhibit Fe—O bonding between the tunnel bather layer 154 and the lower magnetic layer 152, thereby drastically degrading the characteristics of the MTJ. In addition, a portion of the MTJ pattern 150, as well as the metal redeposition material 180′, may be removed by the inert gas ion NA.

In an example embodiment, the oxygen ion OI content of the beam may range from about 1% to about 30%. If the oxygen ion OI content is less than about 1%, a metal oxide may not be sufficiently formed. If the oxygen ion OI content exceeds about 30%, however, oxygen ions OI may diffuse into the MTJ pattern 150, specifically, along the interfaces between the tunnel barrier layer 154 and the upper and lower magnetic layers 152 and 156, and may thereby degrade the MTJ pattern 150.

Referring now to FIG. 3, the third interlayer insulating layer 140 covering the side wall insulating layer 180 may thereafter be formed on the second interlayer insulating layer 130, and the fourth interlayer insulating layer 195 may be formed on the third interlayer insulating layer 140. The upper contact 190 penetrating through the fourth interlayer insulating layer 195 may be formed on the upper electrode 160, and the bit line BL may be formed on the upper contact 190 and the fourth interlayer insulating layer 195.

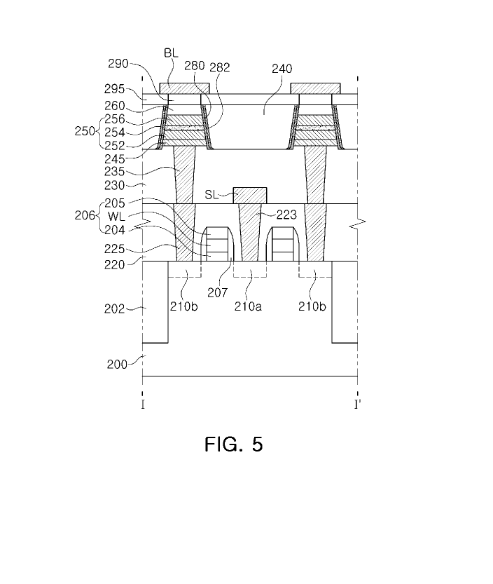

FIG. 5 is a cross-sectional view illustrating a magnetic memory device according to an exemplary embodiment of the present inventive concepts, taken along line I-I′ of FIG. 2.

Referring to FIGS. 2 and 5, isolation patterns 202 defining active patterns ACT may be formed on a substrate 200. The substrate 200 may, for example, be a silicon substrate, a germanium substrate, and/or a silicon-germanium substrate.

The active patterns ACT may be arranged two-dimensionally in a plurality of rows and a plurality of columns, and the active patterns ACT may each have a rectangular shape (or a bar shape) extending in a direction that is diagonal with respect to first and second directions D1 and D2, respectively. The first and second directions D1 and D2, respectively, may be perpendicular to each other. A plurality of active patterns ACT may be arranged in the first direction D1 to form rows, and in the second direction D2 to form columns The active patterns ACT may be doped with a first conductivity-type dopant.

A gate 206 may be disposed on the substrate 200. The gate 206 may include a gate insulating layer pattern 204, a gate electrode WL, and a gate mask 205. A spacer 207 may be disposed on side walls of the gate 206.

A first impurity region 210a and a second impurity region 210b may be formed on the substrate 200 in regions adjacent to the gate 206.

A first interlayer insulating layer 220 may be disposed on the entire surface of the substrate 200. The first interlayer insulating layer 220 may be formed of an oxide (for example, a silicon oxide). First and second contact plugs 223 and 225, respectively, may penetrate through the first interlayer insulating layer 220. The first contact plugs 223 may be electrically connected to the first impurity region 210a. The second contact plugs 225 may be electrically connected to the second impurity regions 210b.

The first and second contact plugs 223 and 225, respectively, may be formed of the same material as that of the first and second contact plugs 123 and 125 illustrated in FIG. 3.

Source lines SL may be disposed on the first interlayer insulating layer 220 and may extend in the first direction D1. The source lines SL may be disposed to traverse the word lines WL. The source lines SL may be connected to the first contact plugs 223 arranged in the first direction D1.

A second interlayer insulating layer 230 may disposed on the first interlayer insulating layer 220, and the second interlayer insulating layer 230 may cover the second contact plugs 225 and the source lines SL.

Lower contacts 235 may be disposed to penetrate through the second interlayer insulating layer 230, and each of the lower contacts 235 may be electrically connected to the second contact plugs 225, respectively. In an exemplary embodiment, the lower contacts 235 may be arranged to be spaced apart from one another in the first direction D1 and the second direction D2 along a plane. The lower contacts 235 may be arranged in a zigzag manner along the plane.

Lower electrodes 245 may be disposed on the lower contacts 135. The lower electrodes 245 may include the same material as the lower electrodes 145 illustrated in FIG. 3.

An MTJ pattern 250 may be disposed on the lower electrodes 235. The MTJ pattern 250 may include a lower magnetic layer 252 and a tunnel barrier layer 254 and an upper magnetic layer 256 disposed on the lower magnetic layer 252.

At least a portion of the lower electrode 245 may be patterned simultaneously with the patterning of the MTJ pattern 250.

In the present exemplary embodiment, a perpendicular magnetic tunnel junction device in which the lower magnetic layer 252 serves as a pinned layer and the upper magnetic layer 256 serves as a free layer will be described as an example. Alternatively, however, a perpendicular magnetic tunnel junction device may have the lower magnetic layer 252 serve as a free layer and the upper magnetic layer 256 serve as a pinned layer.

The lower magnetic layer 252 may include an antiferromagnetic material layer. A magnetization direction of the antiferromagnetic material layer is fixed in a direction substantially parallel to the substrate. The antiferromagnetic material layer may be the same material as that of the antiferromagnetic material layer of the lower magnetic layer 152 illustrated in FIG. 3.

A ferromagnetic material layer may be disposed on the antiferromagnetic material layer of the lower magnetic layer 252. A magnetization direction of the ferromagnetic material layer may be fixed by the antiferromagnetic material layer. The ferromagnetic material layer may be formed of a material that is the same as that of the ferromagnetic material layer of the lower magnetic layer 152 illustrated in FIG. 3.

The tunnel barrier layer 254 may be disposed on the lower magnetic layer 252. The tunnel barrier layer 254 may be formed of the same material as that of the tunnel barrier layer 154 illustrated in FIG. 3.

The upper magnetic layer 256 may be disposed on the tunnel barrier layer 254. The upper magnetic layer 256 may be formed of the same material as that of the upper magnetic layer 156 illustrated in FIG. 3.

An upper electrode 260 may be disposed on the MTJ pattern 250. The upper electrode 260 may be formed of the same material as that of the MTJ pattern 150 illustrated in FIG. 3.

A side wall insulating layer 280 may be formed covering side walls of the MTJ pattern 250, the upper electrode 260, and the lower electrode 245. The side wall insulating layer 280 may include a metal oxide or a metal nitride formed by oxidizing or nitriding a metal included in the MTJ pattern 250, the upper electrode 260, and the lower electrode 245.

A side wall protective layer 282 covering the side wall insulating layer 280 may be formed. The side wall protective layer 282 may act as an electrical insulating layer and may include at least one material selected from the group consisting of boro-phospho-silicate glass (BPSG), tonen silazene (TOSZ), undoped silicate glass (SOG), flowable oxide (FOX), tetraethylortho silicate (TEOS), and a high density plasma chemical vapor deposition (HDP-CVD) oxide.

A third interlayer insulating layer 240 may be disposed on the second interlayer insulating layer 230 covering the side wall protective layer 282, and a fourth interlayer insulating layer 295 may be disposed on the third interlayer insulating layer 240. An upper contact 290 that penetrates through the fourth interlayer insulating layer 295 may be disposed on the upper electrode 260. A bit line BL may be formed on the upper contact 290 and the fourth interlayer insulating layer 295.

The interlayer insulating layers 220, 230, 240, and 295 may be formed of the same material as that of the interlayer insulating layers 120, 130, 140, and 195 illustrated in FIG. 3.

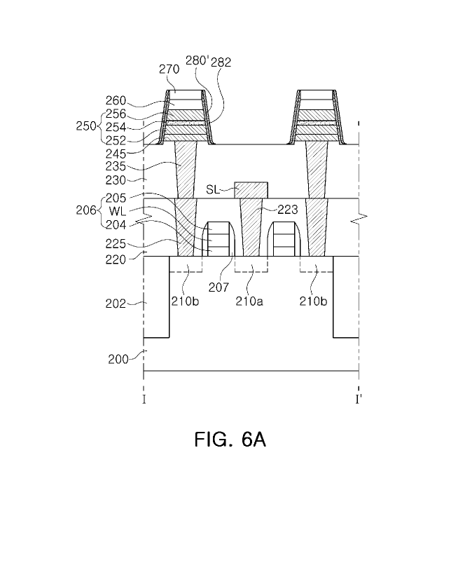

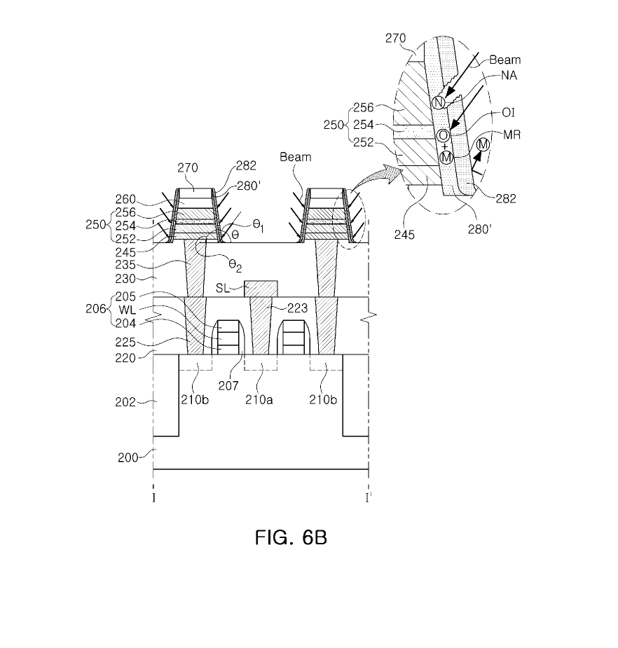

FIGS. 6A and 6B are cross-sectional views taken along line I-I′ of FIG. 2 illustrating sequential processes of a method of manufacturing the magnetic memory device illustrated in FIG. 5. Processes preceding the processes illustrated in FIG. 6A may be the same as those illustrated in FIGS. 4A through 4B.

Referring to FIG. 6A, the lower magnetic layer 252, the tunnel barrier layer 254, the upper magnetic layer 256, and the upper electrode 260 are patterned using the mask pattern 270 as an etching mask to form the MTJ pattern 250. Here, at least a portion of the lower electrode 245 may be patterned.

The patterning may be performed in the same manner as that illustrated in FIG. 4C.

During the patterning process, a metal redeposition material 280′ may be formed by redeposition of etching residue so that the side walls of the upper electrode 260, the MTJ patterns 250, and the lower electrode 245 may be covered. The etching residue may include a metal forming the upper and lower magnetic layers 252 and 256, respectively, included in the MTJ patterns 250 and a metal forming the upper and lower electrodes 245 and 260, respectively. Unfortunately, the upper and lower magnetic layers 252 and 256, respectively, may be electrically connected by the metal redeposition material 280′ which is a conductive material, and the memory device may become defective due to electrical short circuits.

To correct this problem, a side wall protective layer 282 covering the metal redeposition material 280′ may be formed. The side wall protective layer 282 may be formed by forming an insulating layer on the second interlayer insulating layer 230 such that the insulating layer may cover the entire metal redeposition material 280′ and subsequently removing the insulating layer formed on the second interlayer insulating layer 230.

Referring to FIG. 6B, a beam including a reactive ion with respect to the metal forming the metal redeposition material 280′ may be radiated to the side wall protective layer 282, thereby irradiating the side wall protective layer 282. The reactive ion may react with the metal, and a metal insulating material may be formed. More particularly, the reactive ion may be an oxygen ion or a nitrogen ion, and the metal insulating material may be a metal oxide or a metal nitride. The irradiation process may be performed, for example, by ion beam etching. The beam may further include an inert gas ion NA. The inert gas ion NA may remove portions of the side wall protective layer 282 and the metal redeposition material 280′ by etching. An oxygen ion (OI) may penetrate through the portions from which the side wall protective layer 282 and the metal redeposition material 280′ have been removed, and react with at least a portion of a metal MR of the metal redeposition material 280′ to form a metal oxide. By forming the metal oxide, the metal redeposition material 280′ is changed into a side wall insulating layer 280 (see FIG. 5) and electrical short circuits in the memory device may be substantially prevented. The side wall insulating layer 280 (see FIG. 5) may further extend from the side wall of the lower electrode 245 in a direction that is parallel to the substrate 200.

When the internal metal MR is removed and redeposited by irradiating using an ion beam, the internal metal MR may electrically connect the upper and lower magnetic layers 252 and 256, respectively. However, since the side wall protective layer 282 (having electrical insulating properties) is formed covering the metal redeposition material 280′, even though a portion of the internal metal MR is removed and redeposited, generation of electrical short circuits in the memory device may be substantially prevented.

In the irradiation process, the beam may be incident to the metal redeposition material 280′ and the side wall protective layer 282 at an angle (θ) (measured with respect to the substrate 200) ranging from about 15 degrees to about 35 degrees. If the beam angle (θ) is outside of the desired range, the inert gas ion NA may not sufficiently remove the metal redeposition material 280′ and the side wall protective layer 282 and the oxygen ion OI may not sufficiently penetrate through the interior of the metal redeposition material 280′, thereby resulting in insufficient formation of a metal oxide.

Ion beam energy and/or a dose of the oxygen ion OI may be adjusted such that the metal redeposition material 280′ is appropriately oxidized, while preventing oxygen from being diffused to the interior of the MTJ pattern 250.

Otherwise, for example, as explained previously, when the tunnel barrier layer 254 is a metal oxide and the upper and lower magnetic layers 252 and 256 are CoFeB, Fe—O bonding may be inhibited by the oxygen ions diffused through the tunnel barrier layer 254, and the characteristics of the MTJ pattern 250 may be significantly degraded.

As further explained previously, ion beam energy may be about 300 eV or less. If the ion beam energy exceeds about 300 eV, the high energy of the ion beam may result in an excessive amount of oxygen ions OI penetrating to the interior of the MTJ pattern 250. This may inhibit Fe—O bonding between the tunnel bather layer 254 and the lower magnetic layer 252, and the characteristics of the MTJ may therefore be drastically degraded. In addition, the inert gas ion NA may remove a portion of the MTJ pattern 250, as well as the metal redeposition material 280′.

As also discussed previously, the oxygen ion OI content of the beam may range from about 1% to about 30%. If the oxygen ion OI content is less than about 1%, a metal oxide may not be sufficiently formed. Also, if the oxygen ion OI content exceeds about 30%, oxygen ions OI may diffuse into the MTJ pattern 250, specifically, along the interfaces between the tunnel bather layer 254 and the upper and lower magnetic layers 252 and 256, respectively, and may degrade the MTJ pattern 250.

Referring to FIG. 5, the third interlayer insulating layer 540 may be formed on the second interlayer insulating layer 230 covering the side wall protective layer 282, and the fourth interlayer insulating layer 295 may be formed on the third interlayer insulating layer 240. The upper contact 290 may be formed on the upper electrode 260 and may penetrate through the fourth interlayer insulating layer 295. The bit line BL may be formed on the upper contact 290 and the fourth interlayer insulating layer 295.

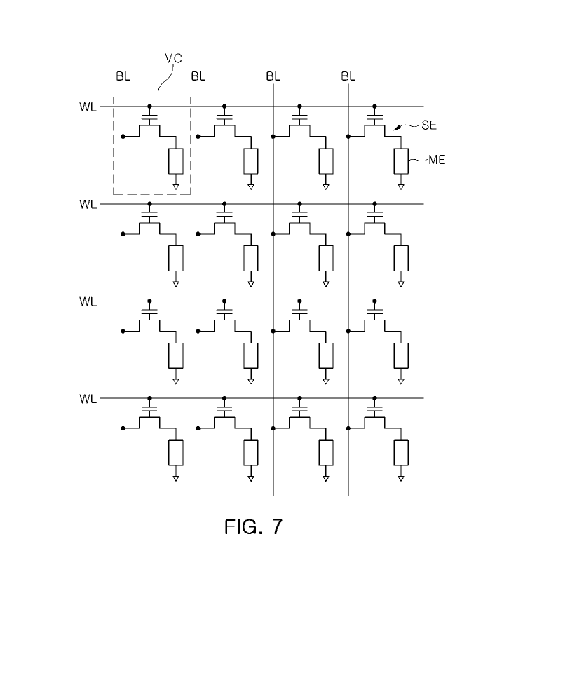

FIG. 7 is a circuit diagram illustrating a cell array of a magnetic memory device according to an exemplary embodiment of the present inventive concepts.

Referring to FIG. 7, a plurality of unit memory cells MC may be arranged two dimensionally or three dimensionally. The unit memory cells MC may be connected between word lines WL and bit lines BL which intersect each other. Each unit memory cell MC may include a magnetic memory element ME and a select element SE. The select elements SE and the magnetic memory elements ME may be electrically connected in series. The magnetic memory elements ME may be connected between the bit lines and the select elements SE, and the select elements SE may be connected between the magnetic memory elements ME and the word lines WL.

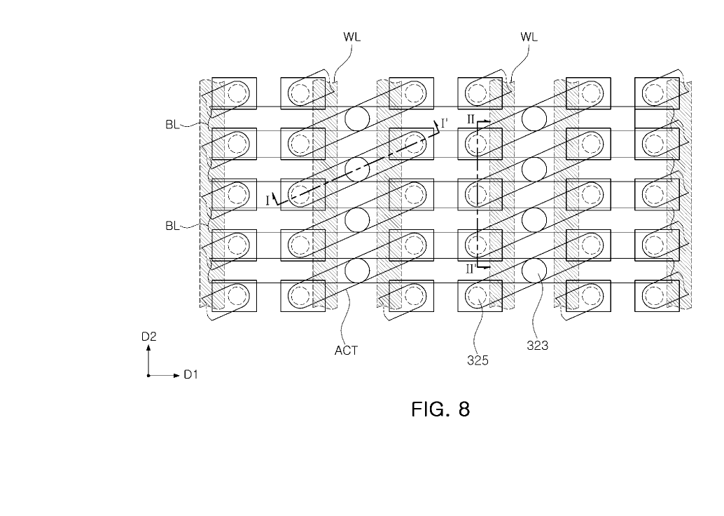

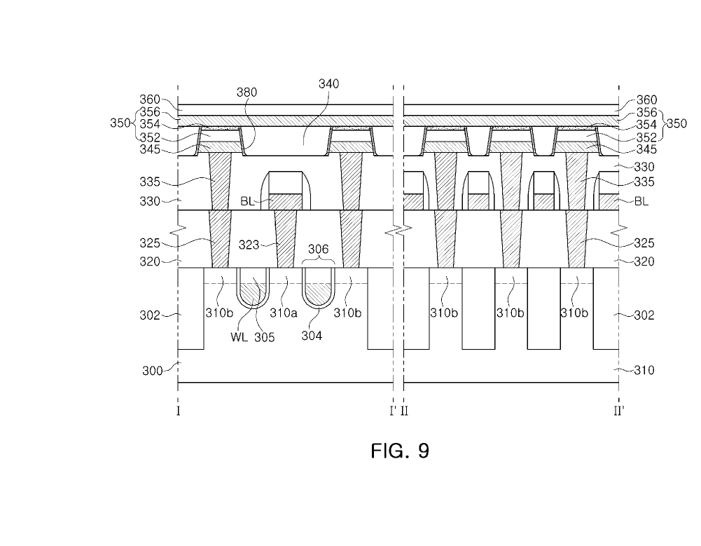

FIG. 8 is a plan view of a magnetic memory device according to an exemplary embodiment of the present inventive concepts. FIG. 9 is a cross-sectional view of the magnetic memory device of FIG. 8, taken along lines I-I′ and II-II′.

Referring to FIGS. 8 and 9, isolation patterns 302 defining active patterns ACT may be formed on a substrate 300. The substrate 300 may, fore example, be a silicon substrate, a germanium substrate, and/or a silicon-germanium substrate.

The active patterns ACT may be arranged two-dimensionally in a matrix form having a plurality of rows and a plurality of columns, and the active patterns ACT may each have a substantially rectangular shape (or bar shape) extending in a direction that is diagonal with respect to both first and second directions D1 and D2, respectively. The first and second directions D1 and D2, respectively, may be perpendicular to each other. A plurality of the active patterns ACT may be arranged in the first direction to form a row, and in the second direction D2 to form a column The active patterns ACT may be doped with a first conductivity-type dopant.

At least one gate 306 may traverse the active patterns ACT forming a column. The gate 306 may be formed in a groove extending in the second direction D2. A depth of the gate 306 may be less than a depth of a lower surface of the isolation pattern 302. In an exemplary embodiment, a pair of gates 306 may traverse the active patterns ACT forming a column In this case, a pair of cell transistors may be formed in each active pattern ACT.

The word lines WL may be disposed within the gates 306, and a gate dielectric layer 304 may be disposed between the word lines WL and the substrate 300. The word lines WL may have a linear form extending in the second direction D2 and traversing the active patterns ACT. The cell transistors may include a channel region of the word lines WL recessed in the gate 306.

A gate hard mask pattern 305 may be disposed on each word line WL. Upper surfaces of the gate hard mask patterns 305 may be substantially coplanar with an upper surface of the substrate 300.

For example, the word lines WL may include at least one material among a semiconductor material doped with a dopant (for example, doped silicon, or the like), a metal (for example, tungsten, aluminum, titanium, and/or tantalum), a conductive metal nitride (for example, a titanium nitride, a tantalum nitride, and/or a tungsten nitride), and a metal-semiconductor compound (for example, a metal silicide).

The gate dielectric layer 304 may include an oxide (for example, a silicon oxide), a nitride (for example, a silicon nitride), an oxynitride (for example, a silicon oxynitride), and/or high K material (for example, an insulating metal oxide such as a hafnium oxide or an aluminum oxide). The gate hard mask pattern 305 may include an oxide (for example, a silicon oxide), a nitride (for example, a silicon nitride), and/or an oxynitride (for example, a silicon oxynitride).

A first impurity region 310a may be disposed within each active pattern ACT on one side of each word line WL, and a second impurity region 310b may be disposed within each active pattern ACT on an opposite side of each word line WL. According to an exemplary embodiment, the first impurity region 310a may be disposed within each active pattern ACT between a pair of word lines WL, and a pair of second impurity regions 310b may be disposed within both edge regions of each active pattern ACT with a pair of word lines WL interposed therebetween. Accordingly, a pair of cell transistors formed in each active pattern ACT may share the first impurity region 310a. The first and second impurity regions 310a and 310b, respectively, correspond to source and drain regions of the cell transistors. The first and second impurity regions 310a and 310b, respectively, may be doped with a second conductivity-type dopant that is different from the first conductivity-type dopant of the active patterns ACT. One of the first and second conductivity-type dopants may, for example, be an N-type dopant, and the other may be a P-type dopant.

A first interlayer insulating layer 320 may be disposed on the entire surface of the substrate 300. The first interlayer insulating layer 320 may be formed of an oxide (for example, a silicon oxide). First and second contact plugs 323 and 325, respectively, may penetrate through the first interlayer insulating layer 320. Each of the first contact plugs 323 may be electrically connected to the first impurity region 310a. Each of the second contact plugs 325 may be electrically connected to the second impurity regions 310b.

The first and second contact plugs 323 and 325, respectively, may be formed of the same material as that of the first and second contact plugs 123 and 125, respectively, illustrated in FIG. 3.

Bit lines BL extending in the first direction D1 may be disposed on the first interlayer insulating layer 320. The bit lines BL may traverse the word lines WL. The bit lines BL may be connected to the first contact plugs 323 arranged in the first direction D1.

A second interlayer insulating layer 330 may disposed on the first interlayer insulating layer 320, and the second interlayer insulating layer 330 may cover the second contact plugs 325 and the bit lines BL. A hard mask pattern may be disposed on the bit lines BL.

Lower contacts 335 may penetrate through the second interlayer insulating layer 330, and each of the lower contacts 335 may be electrically connected to a corresponding one of the second contact plugs 325. In an exemplary embodiment, the lower contacts 335 may be spaced apart from one another in the first direction D1 and the second direction D2. The lower contacts 335 may be arranged in a zigzag pattern along the plane represented by the first and second directions D1 and D2, respectively.

The magnetic memory element ME (see FIG. 7) may be disposed on the lower contacts 335. A lower electrode 345, a lower magnetic layer 352, and a tunnel barrier layer 354, which are patterned, may be sequentially disposed on the lower contact 335. A side wall insulating layer 380 may be disposed covering side walls of the lower electrode 345, the lower magnetic layer 352, and the tunnel barrier layer 354. A third interlayer insulating layer 340 may be disposed on the second interlayer insulating layer 330 covering the side wall insulating layer 380. An upper magnetic layer 356 may be disposed on the patterned tunnel barrier layer 354 and the third interlayer insulating layer 340, and the upper magnetic layer 356 may cover the entirety of the lower magnetic layers 352 arranged two dimensionally on the substrate 300. A higher magnetic layer 356 and a capping insulating layer 360 may be sequentially disposed on the tunnel barrier layer 354.

In the present exemplary embodiment, the lower magnetic layer 352 may serve as a free layer, and the upper magnetic layer 356 may serve as a pinned layer.

More specifically, the lower magnetic layer 352 may include at least one material selected from the group consisting of iron (Fe), cobalt (Co), nickel (Ni), palladium (Pd), and platinum (Pt). For example, the upper magnetic layer 156 may include a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, and/or the like. In other exemplary embodiments, the lower magnetic layer 352 may include at least one material selected from the group consisting of boron (B), carbon (C), copper (Cu), silver (Ag), gold (Au), and chromium (Cr).

The upper magnetic layer 356 may include an antiferromagnetic material layer. A magnetization direction of the antiferromagnetic material layer may be fixed in a direction substantially parallel to the substrate. The antiferromagnetic material layer may include, for example, a platinum-manganese (Pt—Mn) alloy, an iridium-manganese (Ir—Mn) alloy, a nickel-manganese (Ni—Mn) alloy, an iron-manganese (Fe—Mn) alloy, and/or the like.

A ferromagnetic material layer may be disposed on the antiferromagnetic material layer of the upper magnetic layer 356. A magnetization direction of the ferromagnetic material layer may be fixed by the antiferromagnetic material layer. For example, the ferromagnetic material layer may include cobalt (Co), iron (Fe), platinum (Pt), palladium (Pd), and/or the like, and may have a synthetic antiferromagnet (SAF) structure. The SAF structure may be a multilayer structure in which a plurality of magnetic layers and at least one intermediate layer are sequentially stacked. For example, the SAF structure may be a multilayer structure in which a first magnetic layer, an intermediate layer, and a second magnetic layer are sequentially stacked. Alternatively, the SAF structure may be a multilayer structure in which a first magnetic layer, a first intermediate layer, a second magnetic layer, a second intermediate layer, and a third magnetic layer are sequentially stacked. For example, the first magnetic layer may include a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, a Ni—Fe alloy, a Co—Fe alloy, a Ni—Fe—B alloy, a Co—Fe—B alloy, a Ni—Fe—Si—B alloy, a Co—Fe—Si—B alloy, and/or the like. The second and third magnetic layers may include a monolayer formed of cobalt (Co), iron (Fe), platinum (Pt), palladium (Pd), and/or the like, or multiple layers thereof, and the intermediate layer may include ruthenium (Ru), tantalum (Ta), chromium (Cr), copper (Cu), and/or the like.

In the present exemplary embodiment, the lower electrode 345, the lower contact 335, the tunnel barrier layer 354, and the interlayer insulating layers 320, 330, and 340 may be formed of the same material as that of the lower electrode 145, the lower contact 135, the tunnel barrier layer 154, and the interlayer insulating layers 120, 130, and 140.

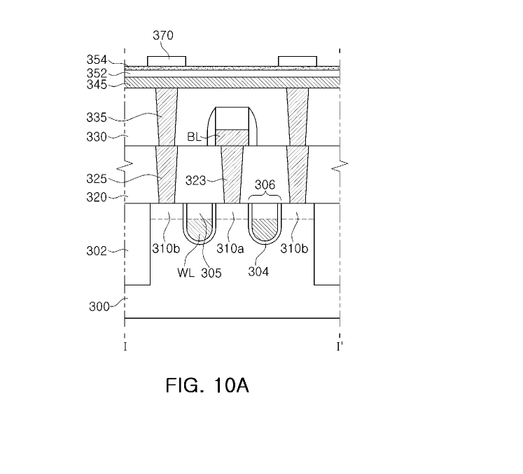

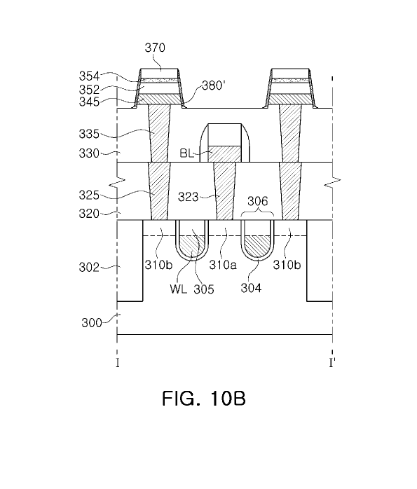

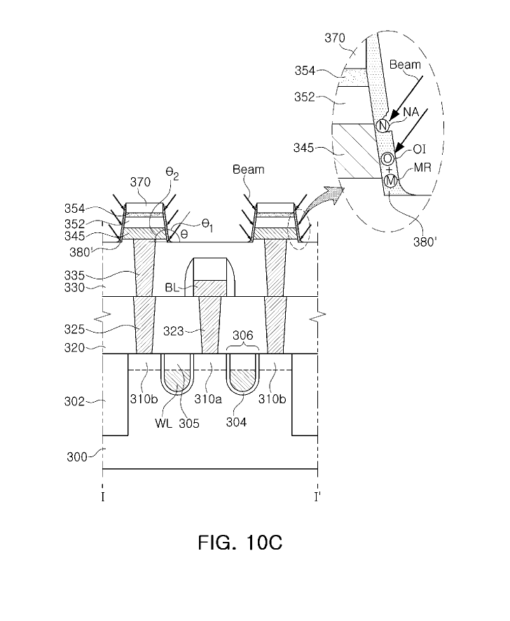

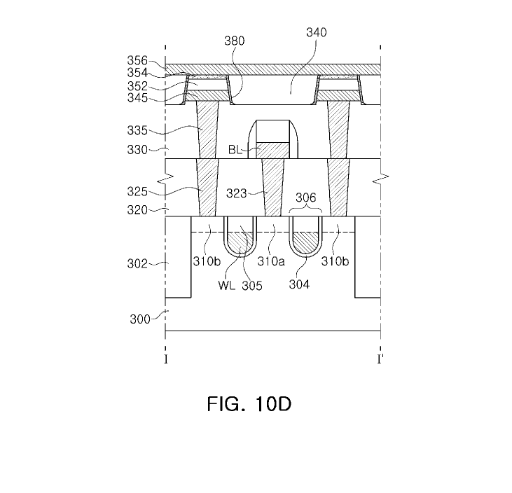

FIGS. 10A through 10D are cross-sectional views illustrating sequential processes of a method of manufacturing a magnetic memory device illustrated in FIG. 9, taken along line I-I′ of FIG. 8.

Referring to FIG. 10A, isolation patterns 302 defining active patterns ACT (see FIG. 8) and a gate 306 having a groove-like shape extending in the second direction may be formed within the substrate 300. A depth of the gate 306 may be smaller than a depth of a lower surface of the isolation pattern 302.

A word line WL may be formed within each gate 306, and a gate dielectric layer 304 may be formed between the substrate 300 and the word line WL.

Gate mask patterns 305 may be formed on the word lines WL such that upper surfaces of gate hard mask patterns 305 are coplanar with an upper surface of the substrate 300.

A first impurity region 310a may be formed on one side of each word line WL, and a second impurity region 310b may be formed on the other side of each word line WL. The first and second impurity regions 310a and 310b, respectively, may be doped with a second conductivity-type dopant that is different from the first conductivity-type dopant of the active pattern ACT (see FIG. 8). One of the first and second conductivity-type dopants may, for example, be an N-type dopant, and the other may be a P-type dopant.

A first interlayer insulating layer 320 may be disposed on the entire surface of the substrate 300. The first and second contact plugs 323 and 325, respectively, may penetrate through the first interlayer insulating layer 320. Each of the first contact plugs 323 may be electrically connected to the first impurity region 310a. Each of the second contact plugs 325 may be electrically connected to the second impurity regions 310b. A method of forming the first and second contact plugs 323 and 325, respectively, may be the same as a method of forming the first and second contact plugs 123 and 125, respectively, of FIG. 4A.

Bit lines BL, extending in the first direction D1 (see FIG. 8), may be disposed on the first interlayer insulating layer 320. The bit lines BL may traverse the word lines WL. The bit lines BL may be connected to the first contact plugs 323 arranged in the first direction D1.

The second interlayer insulating layer 330 may be formed on the first interlayer insulating layer 320 to cover the second contact plugs 325 and the bit lines BL. The lower contact 335 may be formed to penetrate through the second interlayer insulating layer 330. The method of forming the lower contact 335 may be the same as the method of forming the lower contact 135 illustrated in FIG. 4A.

The lower electrode 345 may be formed on the lower contacts 335 and the second insulating layer 330, and the lower magnetic layer 352 may be formed on the lower electrode 345. The tunnel barrier layer 354 may be formed on the lower magnetic layer 352. The mask pattern 370 may be formed on the tunnel barrier layer 354 in a location corresponding to the position of the lower contact 335.

Referring to FIG. 10B, the lower magnetic layer 352 and the tunnel barrier layer 354 may be patterned using the mask pattern 170 as an etching mask. Here, a portion of the lower electrode 345 may be patterned.

The patterning may be performed by dry etching. More specifically, the patterning may be performed by a light ion etching process or a light ion plasma etching process. The light ion etching process may be performed using at least one of hydrogen (H₂), helium (He), nitrogen (N₂), argon (Ar), and neon (Ne), for example. While the etching process is being performed, the upper surface of the second interlayer insulating layer 330 exposed between the lower electrode 345, the lower magnetic layer 352, and the tunnel barrier layer 354 may be recessed.

During the patterning process, a metal redeposition material 180′ may be formed by redeposition of etching residue so that the side walls of the upper electrode, the MTJ patterns 150, and the lower electrode 145 may be covered. The etching residue may include metals forming the lower electrode 345, the upper magnetic layer 356, and the lower magnetic layer 352. The metal redeposition material 380′ formed of the redeposited etching residue may electrically connect the lower magnetic layer 352 and the upper magnetic layer 356 when the mask pattern 370 is removed and the upper magnetic layer 356 is formed on the tunnel barrier layer 354. Electrical short circuits may thereby result in the memory device.

Referring to FIG. 10C, the metal redeposition material 380′ may be irradiated by a beam including a reactive ion with respect to the metal forming the metal redeposition material 380′. The reactive ion may react with the metal, thereby oxidizing the metal redeposition material 380′. The reactive ion may thereby form a metal insulating material by reacting with the metal. More specifically, the reactive ion may be an oxygen ion or a nitrogen ion, and the metal insulating material may be a metal oxide or a metal nitride. The irradiation may be performed, for example, by ion beam etching. The beam may further include an inert gas ion NA, and the inert gas ion NA may remove a portion of the metal redeposition material 380′ by etching. More specifically, the inert gas ion NA may be a noble gas ion, such as a helium (He), neon (Ne), or argon (Ar) gas ion. An oxygen ion (OI) may penetrate through the portion of the side wall from which the metal redeposition material 380′ has been removed, and may react with at least a portion of a metal MR of the metal redeposition material 380′ to form a metal oxide. By forming a metal oxide, the metal redeposition material 380′ may be changed into a side wall insulating layer 380 (see FIG. 10D) and electrical short circuits in the memory device may be substantially prevented. The side wall insulating layer 380 (see FIG. 10D) may extend from the side wall of the lower electrode 345 in a direction parallel to the substrate 300.

The beam may be incident to the metal redeposition material 380′ at an angle (θ) ranging from about 15 degrees to about 35 degrees with respect to the substrate 100. If the beam angle (θ) is outside of the desired range, the inert gas ion NA may not sufficiently remove the metal redeposition material 380′ and the oxygen ion OI may not sufficiently penetrate through the interior of the metal redeposition material 380′, resulting in insufficient formation of a metal oxide.

Ion beam energy and/or a dose of the oxygen ion OI may be adjusted such that the metal redeposition material 380′ is appropriately oxidized, while preventing oxygen from being diffused along the interface between the tunnel barrier layer 354 and the lower magnetic layer 352.

Unfortunately, if the tunnel barrier layer 354 is a metal oxide and the upper and lower magnetic layers 352 and 356, respectively, are CoFeB, Fe—O bonding may be inhibited by oxygen ions diffused through the interface between the tunnel barrier layer 354 and the lower magnetic layer 352, and the characteristics of the MTJ pattern 150 may be significantly degraded.

Accordingly, a desired ion beam energy may be about 300 eV or less. If the ion beam energy exceeds about 300 eV, an excessive amount of oxygen ions OI may penetrate to the interface between the magnetic tunnel barrier layer 354 and the lower magnetic layer 352 due to the high energy of the ion beam. Over-penetration of the oxygen ions OI may inhibit Fe—O bonding between the tunnel barrier layer 354 and the lower magnetic layer 352, and the characteristics of the MTJ may thereby be drastically degraded. Also, if the ion beam energy is too high, portions of the lower electrode 345, the lower magnetic layer 352, and the tunnel barrier layer 354, in addition to the metal redeposition material 380′, may be removed by the inert gas ion NA.

The content of the oxygen ion OI of the beam may range, for example, from about 1% to about 30%. If the content of the oxygen ion OI is less than about 1%, a metal oxide may not be sufficiently formed. Also, if the content of oxygen ion OI exceeds about 30%, oxygen ions OI may diffuse along the interface between the tunnel barrier layer 354 and the lower magnetic layer 352 and may degrade the performance of the MTJ pattern 350.

Referring to FIG. 10D, after the mask pattern 370 (see FIG. 10C) is removed, the third interlayer insulating layer 340 covering the side walls of the side wall insulating layer 380 formed by oxidation of the metal redeposition material 380′ (see FIG. 10C), may be formed on the second interlayer insulating layer 330. The upper magnetic layer 356 may be formed on the third interlayer insulating layer 340 and the tunnel barrier layer 354.

Thereafter, as illustrated in FIG. 9, the capping insulating layer 360 may be formed on the upper magnetic layer 356.

In an embodiment of the present inventive concepts, a three dimensional (3D) memory array may be provided. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array.

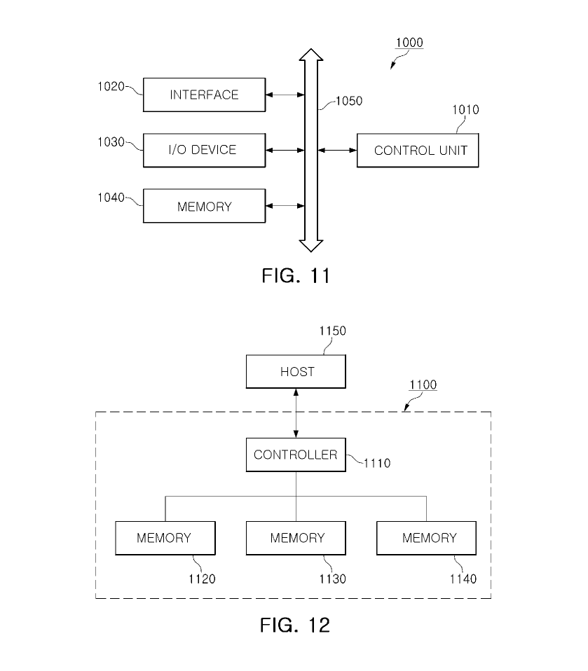

FIGS. 11 and 12 are block diagrams illustrating an electronic device including a magnetic memory device according to an exemplary embodiment of the present inventive concepts.

FIG. 11 is a view illustrating an electronic device 1000 including a magnetic memory device according to an exemplary embodiment of the present inventive concepts. Referring to FIG. 11, the electronic device 1000 according to the present exemplary embodiment may include a control unit 1010, an interface 1020, an input/output device 1030, a memory 1040, and/or the like. The control unit 1010, the interface 1020, the input/output device 1030, the memory 1040, and/or the like, may be connected via a bus (BUS) 1050 providing a passage by which data is delivered.

The control unit 1010 may include a device such as a microprocessor, a digital signal processor, a microcontroller, and/or the like. The memory 1040 may include a device that may read and write data in various manners. The control unit 1010 and the memory 1040 may include any one of the magnetic memory devices according to the various exemplary embodiments of the present inventive concepts described above with reference to FIGS. 1 through 10D.

The input/output device 1030 may, for instance, include a keypad, a keyboard, a touch screen device, a display device, an audio input/output module, and/or the like. The interface 1020 may be a module for transmitting and receiving data via a communications network, and may include an antenna, a wired/wireless transceiver, and/or the like. In addition to the components illustrated in FIG. 11, the electronic device 1000 may further include an application chip set, an imaging device, and/or the like. The electronic device 1000 illustrated in FIG. 11 is not limited in terms of category, and may be various devices such as a personal digital assistant (PDA), a portable computer, a mobile phone, a wireless phone, a laptop computer, a memory card, a portable multimedia player, a tablet PC, and/or the like.

FIG. 12 is a view illustrating a storage device 1100 including a magnetic memory device according to an exemplary embodiment of the present inventive concepts. Referring to FIG. 12, the storage device 1100 according to an exemplary embodiment may include a controller 1100 communicating with a host 1150 and memories 1120, 1130, and 1140 configured to store data. The controller 1110 and the memories 1120, 1130, and 1140 may include one or more of the magnetic memory devices constructed according to various exemplary embodiments described above with reference to FIGS. 1 through 10D.

The host 1150 communicating with the controller 1110 may be any of various electronic devices in which the storage device 1110 is installed. For example, the host 1150 may be a smartphone, a digital camera, a desktop computer, a laptop computer, a media player, and/or the like. The controller 1110 may receive a data write or read request delivered from the host 1150 and may store data in the memories 1120, 1130, and 1140, or may generate a command CMD for retrieving data from the memories 1120, 1130, and 1140.

As illustrated in FIG. 12, one or more memories 1120, 1130, and 1140 may be connected to the controller 1110 in parallel within the storage device 1100. By connecting the plurality of memories 1120, 1130, and 1140 to the controller 1110 in parallel, a large capacity storage device 1100 may be realized.

A method of manufacturing a magnetic memory device, according to exemplary embodiments of the present inventive concepts, may substantially prevent oxygen from penetrating to the interior of a magnetic tunnel junction while a metal redeposition material formed on the side walls of the magnetic tunnel junction is oxidized.

While exemplary embodiments have been shown and described above, it will be apparent to those skilled in the art that modifications and variations could be made without departing from the scope of the present inventive concepts as defined by the appended claims.

1. A method of manufacturing a magnetic memory device, the method comprising:
forming a lower magnetic layer, a tunnel barrier layer, and an upper magnetic layer on a substrate;
forming a magnetic tunnel junction (MTJ) pattern by patterning the lower magnetic layer, the tunnel barrier layer, and the upper magnetic layer; and
irradiating a side wall of the MTJ pattern with a beam including an oxygen ion,
wherein, in the forming of the MTJ pattern, a metal redeposition material covering the side wall of the MTJ pattern is formed and the metal redeposition material is irradiated by the beam.

2. The method of claim 1, wherein the metal redeposition material is formed by removal of portions of the upper and lower magnetic layers and deposition thereof on the side wall of the MTJ pattern.

3. The method of claim 1, wherein the oxygen ion oxidizes at least a portion of the metal redeposition material.

4. The method of claim 1, wherein at least a portion of the metal redeposition material is removed by the beam.

5. The method of claim 1, wherein the beam includes an inert gas ion.

6. The method of claim 1, wherein the beam is incident at an angle ranging from about 15 degrees to about 35 degrees with respect to the substrate.

7. The method of claim 1, wherein the beam is supplied by ion beam etching.

8. The method of claim 1, wherein a dose of the oxygen ion is adjusted such that the oxygen ion does not penetrate to the interior of the MTJ pattern.

9. The method of claim 1, wherein the content of the oxygen ion of the beam ranges from about 1% to about 30%.

10. The method of claim 1, wherein the MTJ pattern is formed by dry etching.

11. The method of claim 1, wherein the tunnel barrier layer is formed of any one or more materials selected from the group consisting of magnesium oxide (MgO), an aluminum oxide (Al₂O₃), a silicon oxide (SiO₂), and a boron oxide (B₂O₃).

12. The method of claim 1, wherein, in the forming of the MTJ pattern, the metal redeposition material is formed on the side wall of the MTJ pattern, and
wherein the method further includes forming a side wall protective layer on the metal redeposition material before irradiating with the beam.

13. The method of claim 12, wherein the side wall protective layer is formed of an insulating material.

14. A method of manufacturing a magnetic memory device, the method comprising:
forming a magnetic tunnel junction (MTJ) pattern on a substrate by dry-etching a lower magnetic layer, a tunnel barrier layer, and an upper magnetic layer, wherein a metal layer covering a side wall of the MTJ pattern is formed; and
forming a side wall insulating layer by irradiating the side wall using a beam including a reactive ion with respect to the metal layer and further including an inert gas ion.

15. The method of claim 14, wherein a dose of the reactive ion is adjusted such that the reactive ion does not penetrate to the interior of the MTJ pattern.

16. The method of claim 14, wherein the reactive ion forms a metal insulating material by reacting with the metal layer.

17. The method of claim 14, wherein the reactive ion is an oxygen ion or a nitrogen ion.

18-26. (canceled)

27. A method of forming a magnetic memory device having a magnetic tunnel junction (MTJ) pattern, said method comprising:
irradiating a metal redeposition material formed on a side wall of the MTJ pattern using a beam including an oxygen ion to oxidize the metal redeposition material,
wherein an ion beam energy and an oxygen ion content of the beam is selected to prevent penetration by the oxygen into the interior of the MTJ pattern while sufficiently oxidizing the metal redeposition material to prevent electrical short circuits along the side wall of the MTJ pattern.

28. The method of claim 27, wherein the ion beam energy is below about 300 eV and wherein the oxygen ion content of the beam is between about 1% and about 30%.

29. A method according to claim 27, further including forming a side wall protective film on the metal redeposition material before irradiating the metal redeposition material to form an insulating layer that helps protect against electrical short circuits along the side wall of the MTJ pattern.

30. (canceled)
